(19) United States
(12) Patent Application Publication
(10) Pub. No.: US 2025/0138112 A1
(43) Pub. Date: May 1, 2025

(54) SUPERCONDUCTING READOUT SYSTEM

(71) Applicant: NORTHROP GRUMMAN SYSTEMS CORPORATION, FALLS CHURCH, VA (US)

(72) Inventor: JOSHUA A. STRONG, Ellicott City, MD (US)

(21) Appl. No.: 18/499,856

(22) Filed: Nov. 1, 2023

(51) Int. Cl. G01R 33/035; G01R 33/00

(52) U.S. Cl. CPC G01R 33/0358; G01R 33/0041; G01R 33/0356

(57) ABSTRACT

One example includes a superconducting readout system. The system includes an RF hybrid coupler configured to receive an RF input signal and to generate at least one RF tuning signal and an RF output signal based on the RF input signal. The system also includes at least one tunable resonator system comprising a tunable resonator configured to receive the respective RF tuning signal(s). Each of the tunable resonator(s) can have a resonant frequency that is set by a superconducting input signal, such that the RF tuning signal(s) is reflected back to the RF hybrid coupler to provide a variable phase-shift of the RF output signal relative to the RF input signal that is based on the superconducting input signal. The system further includes a phase monitor configured to measure a phase difference between the RF input signal and the RF output signal to determine the superconducting input signal.

### GOVERNMENT INTEREST

The invention was made under Government Contract. Therefore, the US Government has rights to the invention as specified in that contract.

### TECHNICAL FIELD

The present invention relates generally to computer systems, and specifically to a superconducting readout system.

### BACKGROUND

Superconducting digital technology has provided computing and/or communications resources that benefit from unprecedented high speed, low power dissipation, and low operating temperature. Superconducting digital technology has been developed as an alternative to CMOS technology, and typically comprises superconductor based single flux superconducting circuitry, utilizing superconducting Josephson junctions, and can exhibit typical signal power dissipation of less than 1 nW (nanowatt) per active device at a typical data rate of 20 Gb/s (gigabytes/second) or greater, and can operate at temperatures of around 4 Kelvin.

Superconducting circuits, such as reciprocal quantum logic (RQL) circuits, typically require readout circuitry to read digital signals that are provided in the form of flux pulses (e.g., fluxons) or the absence thereof. Typically, a readout circuit can be fabricated as an amplifier, such as implemented with a stack arrangement of one or more superconducting quantum interference devices (SQUIDs) that include Josephson junctions that switch to a voltage state when triggered by an input fluxon. Such readout circuits can provide suitable readout of a serial data stream of fluxons at sufficient speed at a rate of one bit per clock cycle.

### SUMMARY

One example includes a superconducting readout system. The system includes an RF hybrid coupler configured to receive an RF input signal and to generate at least one RF tuning signal and an RF output signal based on the RF input signal. The system also includes at least one tunable resonator system comprising a tunable resonator configured to receive the respective RF tuning signal(s). Each of the tunable resonator(s) can have a resonant frequency that is set by a superconducting input signal, such that the RF tuning signal(s) is reflected back to the RF hybrid coupler to provide a variable phase-shift of the RF output signal relative to the RF input signal that is based on the superconducting input signal. The system further includes a phase monitor configured to measure a phase difference between the RF input signal and the RF output signal to determine the superconducting input signal.

Another example includes a method for reading a superconducting input signal. The method includes receiving the superconducting input signal as a binary code and providing at least one flux quanta into at least one superconducting quantum interference device (SQUID) associated with a respective at least one tunable resonator to define a resonant frequency of the at least one tunable resonator. The method also includes providing an RF input signal to an input of an RF hybrid coupler. The RF hybrid coupler can be configured to generate an RF output signal and at least one RF tuning signal based on the RF input signal. The at least one RF tuning signal can be provided to and reflected back from the respective at least one tunable resonator to provide a variable phase-shift of the RF output signal relative to the RF input signal. The method further includes measuring a phase difference between the RF input signal and the RF output signal to determine a value of the binary code of the superconducting input signal.

Another example includes a superconducting readout system. The system includes an RF hybrid coupler configured to receive an RF input signal and to generate at least one RF tuning signal and an RF output signal based on the RF input signal. The system also includes a tunable resonator system. The tunable resonator system includes a tuning pulse generator system that is configured to generate a plurality of tuning pulses based on the superconducting input signal and at least one tunable resonator comprising a transmission line and a superconducting quantum interference device (SQUID). Each of the at least one tunable resonator can have a resonant frequency that is set by a quantity of flux quanta in the respective SQUID in response to the tuning pulses, such that the at least one RF tuning signal is provided to each of the respective at least one tunable resonator and is reflected back to the RF hybrid coupler to provide a variable phase-shift of the RF output signal relative to the RF input signal that is based on the superconducting input signal. The system further includes a phase monitor configured to measure a phase difference between the RF input signal and the RF output signal to determine the superconducting input signal.

### BRIEF DESCRIPTION OF THE DRAWINGS

FIG. 1 illustrates an example block diagram of a superconducting readout system.

FIG. 2 illustrates an example of a superconducting readout system.

FIG. 3 illustrates an example diagram of a tuning pulse generator system.

FIG. 4 illustrates an example of a method for reading a superconducting input signal.

### DETAILED DESCRIPTION

The present invention relates generally to computer systems, and specifically to a superconducting readout system. The superconducting readout system can be implemented in any of a variety of superconducting computer circuits to provide readout of a digital signal formed by fluxons. As described herein, the terms “fluxon” and “pulse” each refer to a superconducting pulse signal, such as a single flux quantum (SFQ) pulse or a reciprocal quantum logic (RQL) pulse that includes a positive fluxon followed by a negative fluxon. Thus, as described herein, in the context of a binary signal, the term “pulse” can refer to the presence of a fluxon to indicate a first binary state or the absence of a fluxon to indicate a second binary state that is opposite the first binary state.

The superconducting readout system includes a radio frequency (RF) hybrid coupler. The RF hybrid coupler can be arranged as a coupled transmission line that can be arranged as a reflective phase-shifter. Therefore, in response to an RF input signal provided in an input port of the RF hybrid coupler, and based on termination of two other ports of the RF hybrid coupler with an approximately equal reactance, the RF input signal can generate an RF tuning signal on the terminated two ports that are reflected back to the RF hybrid coupler to provide a phase-shift of an RF output signal provided from a fourth port that is based on the RF input signal. The phase-shift of the RF output signal relative to the RF input signal can be based on the reactance of the terminated ports.

As described herein, the superconducting readout system can thus include a tunable resonator system that is coupled to the RF hybrid coupler to provide the reactance to the terminated ports of the RF hybrid coupler. The tunable resonator system can include at least one (e.g., two) tunable resonators that are each formed from a transmission line and a terminated alternating current (AC) superconducting quantum interference device (hereinafter “SQUID”). Each tunable resonator can thus have a resonant frequency that is adjustable based on a flux associated with the respective SQUID. For each flux quantum that is stored in the SQUID, the tunable resonator can have a different resonant frequency that therefore affects the phase-shift of the RF output signal relative to the RF input signal. As an example, each tunable resonator can provide a known phase-shift increment of the RF output signal relative to the RF input signal for each flux quantum provided to the SQUID.

The tunable resonator system also includes a tuning pulse generator system that is configured to receive a superconducting input signal. The superconducting input signal can correspond to a parallel superconducting logic signal that is provided as a binary code. For example, the superconducting readout system can be configured as a quadrature-amplitude modulation (QAM) readout circuit, such that the superconducting input signal can be provided as a two-bit binary code based on a parallel pair of superconducting pulses, thereby having one of four different binary values. The tuning pulse generator system can thus generate a plurality of tuning pulses based on the superconducting input signal, with each of the tuning pulses providing a discrete flux quantum to each SQUID of the tunable resonator(s). For example, the tuning pulse generator system can include at least one pulse splitter to split a respective superconducting bit of the superconducting input signal into multiple tuning pulses, such that each superconducting bit of the superconducting input signal can be represented by a unique quantity of tuning pulses. Accordingly, the SQUID(s) of the respective tunable resonator(s) can have a quantity of flux quanta that can correspond to a known phase-shift of the RF output signal relative to the RF input signal.

The superconducting readout system can further include a phase monitor that is configured to measure a phase difference between the RF input signal and the RF output signal to determine the superconducting input signal. For example, the phase monitor can identify the phase-difference between the RF output signal and the RF input signal. In response to determining the phase-difference, the phase monitor can identify the quantity of flux quanta in the SQUID(s) of the tunable resonator(s), and can thus determine a corresponding value of the binary code associated with the superconducting input signal. Accordingly, the phase monitor can determine the value of the binary code of the superconducting input signal in response to determining the phase-shift of the RF output signal relative to the RF input signal.

The superconducting readout system can thus provide an improvement over a conventional superconducting readout circuit. As a first example, the SQUIDs in a conventional superconducting readout circuit can be arranged as direct current (DC) SQUIDs in which the Josephson junctions trigger and operate in the voltage state in response to a superconducting pulse. In the voltage state, the Josephson junctions can provide high frequency (e.g., at least 100 GHz) noise that can be deleterious to other sensitive circuitry in the circuit. By contrast, the Josephson junction of the AC SQUID(s) do not trigger to enter the voltage stage, and instead, the AC SQUID(s) merely operate as variable inductors that reflect the RF tuning signal back to the RF hybrid coupler to provide the phase-shift of the RF output signal. Furthermore, conventional superconducting readout circuits operate on a serial data stream, and thus a single bit per clock cycle, which the superconducting readout system described herein can operate on a parallel multi-bit superconducting signal, and thus multiple bits per clock cycle. Accordingly, the superconducting readout system described herein can provide for a more effective superconducting signal readout.

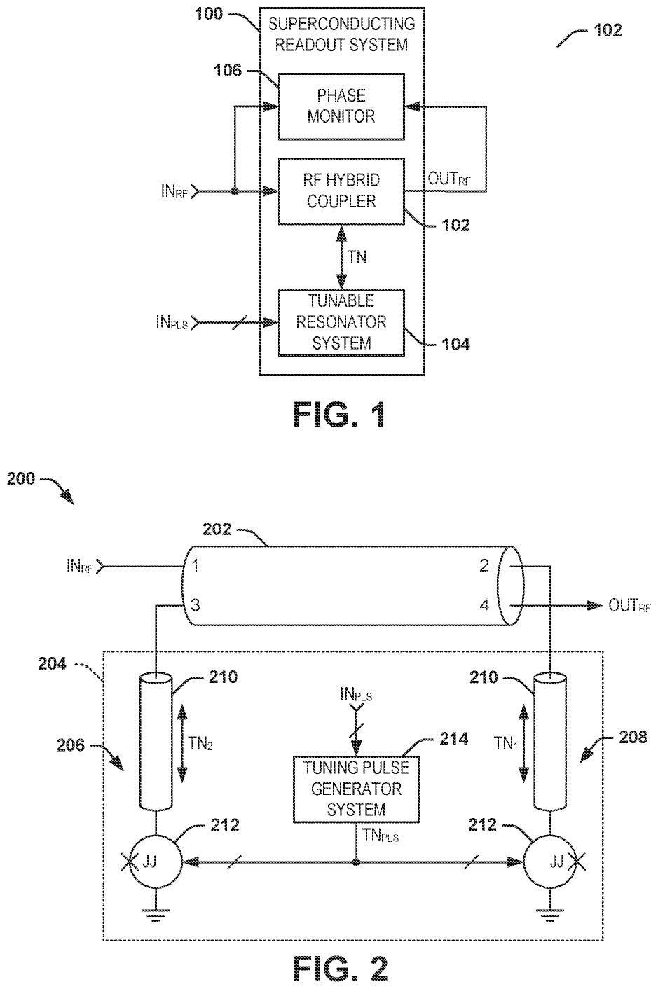

FIG. 1 illustrates an example block diagram of a superconducting readout system 100. The superconducting readout system 100 can be implemented in any of a variety of superconducting computer circuits to provide readout of a digital signal formed by fluxons.

The superconducting readout system 100 includes an RF hybrid coupler 102. The RF hybrid coupler 102 can be arranged as a coupled transmission line that can be arranged as a reflective phase-shifter. In the example of FIG. 1, the RF hybrid coupler 102 receives an RF input signal IN_{RF} that is provided to an input port of the RF hybrid coupler 102. The RF hybrid coupler 102 can also include an output port that is configured to provide an RF output signal OUT_{RF} based on the RF input signal IN_{RF}, and one or more (e.g., two) tuning ports that can provide a respective one or more RF tuning signals TN.

In the example of FIG. 1, the superconducting readout system 100 includes a tunable resonator system 104 that is coupled to the tuning ports of the RF hybrid coupler 102, and is thus configured to receive the tuning signal(s) TN. As an example, the tunable resonator system 104 can include at least one (e.g., two) tunable resonator that is configured to propagate the respective tuning signal(s) TN, and can reflect the tuning signal(s) TN back to the RF hybrid coupler 102 to provide a phase-shift of the RF output signal OUT_{RF} relative to the RF input signal IN_{RF}. The amount of phase-shift of the RF output signal OUT_{RF} relative to the RF input signal IN_{RF} can be based on the reactance of the tunable resonator(s) of the tunable resonator system 104, and thus the resonant frequency of the tunable resonator(s).

As an example, the tunable resonator(s) of the tunable resonator system 104 can include a transmission line and a terminated AC SQUID. Each tunable resonator can thus have a resonant frequency that is adjustable based on a flux associated with the respective SQUID. For example, for each flux quantum that is stored in the SQUID, a given one of the tunable resonator(s) can have a different defined resonant frequency that therefore affects the phase-shift of the RF output signal OUT_{RF} relative to the RF input signal IN_{RF}. As an example, each tunable resonator can provide a known phase-shift increment of the RF output signal OUT_{RF} relative to the RF input signal IN_{RF} for each flux quantum provided to the SQUID in a linear additive manner (e.g., for a maximum phase-shift of approximately 180°, each flux quantum can provide 22.5° of phase-shift, as described in an example herein).

As an example, the tunable resonator system 104 can include a tuning pulse generator system that is configured to receive a superconducting input signal IN_{PLS}. The superconducting input signal IN_{PLS} can, for example, correspond to a parallel superconducting logic signal that is provided as a binary code. For example, the superconducting readout system 100 can be configured as a QAM readout circuit, such that the superconducting input signal IN_{PLS} can be provided as a two-bit binary code based on a parallel pair of superconducting pulses, thereby having one of four different binary values. The tuning pulse generator system can thus generate a plurality of tuning pulses based on the superconducting input signal IN_{PLS}, with each of the tuning pulses providing a discrete flux quantum to each SQUID of the respective tunable resonator(s). For example, the tuning pulse generator system can include at least one pulse splitter to split a respective superconducting bit of the superconducting input signal IN_{PLS} into multiple tuning pulses, such that each superconducting bit of the superconducting input signal IN_{PLS} can be represented by a unique quantity of tuning pulses. Accordingly, the SQUID(s) of the respective tunable resonator(s) can have a quantity of flux quanta that can correspond to a known phase-shift of the RF output signal OUT_{RF} relative to the RF input signal IN_{RF}.

The superconducting readout system 100 further includes a phase monitor 106 that is configured to measure a phase difference between the RF input signal IN_{RF} and the RF output signal OUT_{RF} to determine the superconducting input signal IN_{PLS}. For example, the phase monitor 106 can identify the phase-difference between the RF output signal OUT_{RF} and the RF input signal IN_{RF}. In response to determining the phase-difference, the phase monitor 106 can identify the quantity of flux quanta in the SQUID(s) of the tunable resonator(s), and can thus determine a corresponding value of the binary code associated with the superconducting input signal IN_{PLS}. Accordingly, the phase monitor can determine the value of the binary code of the superconducting input signal IN_{PLS} in response to determining the phase-shift of the RF output signal OUT_{RF} relative to the RF input signal IN_{RF}.

FIG. 2 illustrates an example of a superconducting readout system 200. The superconducting readout system 200 can correspond to one example of the superconducting readout system 100 in the example of FIG. 1.

The superconducting readout system 200 includes an RF hybrid coupler 202 that is configured as a coupled transmission line arranged as a reflective phase-shifter. In the example of FIG. 2, the RF hybrid coupler 202 receives an RF input signal IN_{RF} at an input port (“1”) of the RF hybrid coupler 202. The RF hybrid coupler 202 can also include an output port (“4”) that is configured to provide an RF output signal OUT_{RF} based on the RF input signal IN_{RF}, and a pair of tuning ports (“2” and “3”) that can provide a respective pair of RF tuning signals, demonstrated as a first RF tuning signal TN₁ and a second RF tuning signal TN₂ likewise based on the RF input signal IN_{RF}. As described in greater detail herein, the RF input signal IN_{RF} can be provided to interrogate the binary value for readout of a superconducting input signal.

In the example of FIG. 2, the superconducting readout system 200 includes a tunable resonator system 204. The tunable resonator system 204 includes a first tunable resonator 206 that is configured to propagate the first RF tuning signal TN₁ and a second tunable resonator 208 that is configured to propagate the second RF tuning signal TN₂. In the example of FIG. 2, each of the tunable resonators 206 and 208 includes a transmission line 210 and a terminated AC SQUID 212 that includes a Josephson junction JJ. As described herein, the tunable resonators 206 and 208 can each reflect the respective tuning signals TN₁ and TN₂ back to the RF hybrid coupler 202 to provide a phase-shift of the RF output signal OUT_{RF} relative to the RF input signal IN_{RF} that is based on the resonant frequency of the respective tunable resonators 206 and 208.

As described herein, each of the tunable resonators 206 and 208 can have a resonant frequency that is adjustable based on a flux associated with the SQUIDs 212. For example, for each flux quantum that is stored in each of the SQUIDs 212, the tunable resonators 206 and 208 can each have a different defined resonant frequency that therefore affects the phase-shift of the RF output signal OUT_{RF} relative to the RF input signal IN_{RF}. As an example, each of the tunable resonators 206 and 208 can provide a known phase-shift increment of the RF output signal OUT_{RF} relative to the RF input signal IN_{RF} for each flux quantum provided to the respective SQUIDs 212 in a linear additive manner. As described herein, the same quantity of flux quanta can be provided to each of the SQUIDs 212, such that the tunable resonators 206 and 208 can have approximately the same resonant frequency.

Because the SQUIDs 212 are configured as AC SQUIDs, as opposed to DC SQUIDs, the flux quanta can be provided in a manner that does not trigger the Josephson junction to enter the voltage state, but instead merely provides a variable inductance of the SQUID 212 to modify the reactance, and therefore the resonant frequency, of the respective tunable resonators 206 and 208. Accordingly, the superconducting readout system 200 can operate without the noise associated with Josephson junctions operating in the voltage state, in contrast to conventional superconducting readout systems.

In the example of FIG. 2, the tunable resonator system 204 includes a tuning pulse generator system 214 that is configured to receive a superconducting input signal IN_{PLS}. The superconducting input signal IN_{PLS} can correspond to a parallel superconducting logic signal that is provided as a binary code. For example, the superconducting readout system 200 can be configured as a QAM readout circuit, such that the superconducting input signal IN_{PLS} can be provided as a two-bit binary code based on a parallel pair of superconducting pulses, thereby having one of four different binary values. However, the superconducting input signal IN_{PLS} can instead include a single bit, or can include more than two bits, as described in greater detail herein.

The tuning pulse generator system 214 can thus generate a plurality of tuning pulses TN_{PLS} based on the binary value of the superconducting input signal IN_{PLS}, with each of the tuning pulses TN_{PLS} providing a discrete flux quantum to each of the SQUIDs 212 of the respective tunable resonators 206 and 208. For example, the tuning pulse generator system 214 can include at least one pulse splitter to split a respective superconducting bit of the superconducting input signal IN_{PLS} into multiple tuning pulses TN_{PLS}, such that each superconducting bit of the superconducting input signal IN_{PLS} can be represented by a unique quantity of tuning pulses TN_{PLS}. Accordingly, the SQUIDs 212 of the respective tunable resonators 206 and 208 can have a quantity of flux quanta that can correspond to a known phase-shift of the RF output signal OUT_{RF} relative to the RF input signal IN_{RF}. Accordingly, a phase monitor (not shown in the example of FIG. 2), such as the phase monitor 106 in the example of FIG. 1, can determine the binary value of the superconducting input signal IN_{PLS} based on identifying the phase-difference between the RF output signal OUT_{RF} and the RF input signal IN_{RF}.

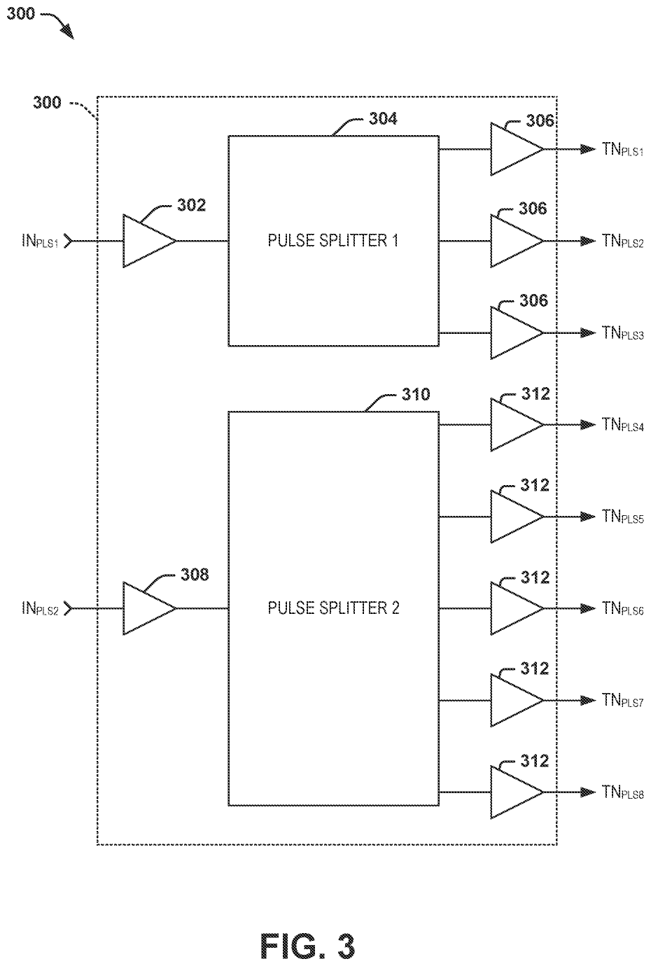

FIG. 3 illustrates an example diagram of a tuning pulse generator system 300. The tuning pulse generator system 300 can correspond to the tuning pulse generator system 214 in the example of FIG. 2. Therefore, reference is to be made to the example of FIG. 2 in the following example of FIG. 3.

The tuning pulse generator system 300 is demonstrated in the example of FIG. 3 as receiving a two-bit parallel superconducting input signal IN_{PLS}, demonstrated as including a first superconducting input signal portion IN_{PLS1} and a second superconducting input signal portion IN_{PLS2}. Therefore, the two-bit superconducting input signal IN_{PLS} can have one of four possible binary code values based on the presence of or absence of a pulse in each of the superconducting input signal portions IN_{PLS1} and IN_{PLS2}. The first and second superconducting input signal portions IN_{PLS1} and IN_{PLS2} can be provided concurrently, and thus on the same clock cycle of an associated clock (e.g., an RQL clock), to facilitate concurrent readout of the superconducting input signal portions IN_{PLS1} and IN_{PLS2}, and thus readout of the multi-bit parallel superconducting input signal IN_{PLS} on a single clock cycle. Accordingly, the superconducting readout system 200 can operate in a more time-efficient manner than conventional superconducting readout systems that readout single bits in a serial data stream.

The tuning pulse generator system 300 includes a Josephson transmission line (JTL) 302 that propagates the first superconducting input signal portion IN_{PLS1} to a first pulse splitter 304. The first pulse splitter 304 is configured to convert the first superconducting input signal portion IN_{PLS1} into three same value tuning pulses TN_{PLS1}, TN_{PLS2}, and TN_{PLS3} that each correspond to the first superconducting input signal portion IN_{PLS1}. Therefore, if the first superconducting input signal portion IN_{PLS1} has a binary value of “0”, then the tuning pulses TN_{PLS1}, TN_{PLS2}, and TN_{PLS3} likewise each have a binary value of “0”, and if the first superconducting input signal portion IN_{PLS1} has a binary value of “1”, then the tuning pulses TN_{PLS1}, TN_{PLS2}, and TN_{PLS3} likewise each have a binary value of “1”. The tuning pulses TN_{PLS1}. TN_{PLS2}, and TN_{PLS3} are output from the tuning pulse generator system 300 via respective JTLs 306 to each of the SQUIDs 212 to provide (or not provide) three discrete flux quanta.

The tuning pulse generator system 300 also includes a JTL 308 that propagates the second superconducting input signal portion IN_{PLS2} to a second pulse splitter 310. The second pulse splitter 310 is configured to convert the second superconducting input signal portion IN_{PLS2} into five same value tuning pulses TN_{PLS4}, TN_{PLS5}, TN_{PLS6}, TN_{PLS7}, and TN_{PLS8} that each correspond to the second superconducting input signal portion IN_{PLS2}. Therefore, the first and second superconducting input signal portions IN_{PLS1} and IN_{PLS2} have a unique quantity of tuning pulses TN_{PLS} associated therewith. Therefore, if the second superconducting input signal portion IN_{PLS2} has a binary value of “0”, then the tuning pulses TN_{PLS4}, TN_{PLS5}, TN_{PLS6}, TN_{PLS7}, and TN_{PLS8} likewise each have a binary value of “0”, and if the second superconducting input signal portion IN_{PLS2} has a binary value of “1”, then the tuning pulses TN_{PLS4}, TN_{PLS5}, TN_{PLS6}, TN_{PLS7}, and TN_{PLS8} likewise each have a binary value of “1”. The tuning pulses TN_{PLS4}, TN_{PLS5}, TN_{PLS6}, TN_{PLS7}, and TN_{PLS8} are output from the tuning pulse generator system 300 via respective JTLs 312 to each of the SQUIDs 212 to provide (or not provide) five discrete flux quanta.

With reference to FIGS. 2 and 3, as one example, the superconducting readout system 200 can be fabricated to have a maximum phase-shift of the RF output signal OUT_{RF} relative to the RF input signal IN_{RF} of approximately 180°, such as based on the inductance parameters of the RF hybrid coupler 202, the transmission lines 210, and/or the SQUIDs 212. Additionally in this example, the SQUIDs 212 can be fabricated to be able to accommodate a maximum of eight total flux quanta. Therefore, each of the tuning pulses TN_{PLS} can provide a single discrete flux quantum that results in an approximate 22.5° phase-shift of the RF output signal OUT_{RF} relative to the RF input signal IN_{RF}. Accordingly, the associated phase monitor (e.g., the phase monitor 106) can determine the value of the binary code of the multi-bit superconducting input signal IN_{PLS} based on the identified phase-shift of the RF output signal OUT_{RF} relative to the RF input signal IN_{RF}. As described herein, the unique quantity of tuning pulses TN_{PLS} can be implemented by the phase monitor to identify the different binary values of each bit of the superconducting input signal IN_{PLS}.

With reference to the example above, by additional example, presence of a pulse in the superconducting input signal portions IN_{PLS1} and IN_{PLS2} can correspond to a respective logic-high binary state, and absence of a pulse in the superconducting input signal portions IN_{PLS1} and IN_{PLS2} can correspond to a respective logic-low binary state. Thus, if the phase monitor determines a phase-shift of the RF output signal OUT_{RF} relative to the RF input signal IN_{RF} of approximately 0°, then the phase monitor determines that there is no flux quanta in the SQUIDs 212, which is based on all of the tuning pulses TN_{PLS} being logic-low (e.g., no pulse). Therefore, the phase monitor determines that the first superconducting input signal portion IN_{PLS1} and the second superconducting input signal portion IN_{PLS2} each have a logic-low value for a corresponding “00” binary code. If the phase monitor determines a phase-shift of the RF output signal OUT_{RF} relative to the RF input signal IN_{RF} of approximately 67.5°, then the phase monitor determines that there are three flux quanta in the SQUIDs 212, which is based on three of the tuning pulses TN_{PLS} being logic-high (e.g., pulses). Therefore, the phase monitor determines that the first superconducting input signal portion IN_{PLS1} has a logic-high value and the second superconducting input signal portion IN_{PLS2} has a logic-low value for a corresponding “10” binary code.

If the phase monitor determines a phase-shift of the RF output signal OUT_{RF} relative to the RF input signal IN_{RF} of approximately 112.5°, then the phase monitor determines that there are five flux quanta in the SQUIDs 212, which is based on five of the tuning pulses TN_{PLS} being logic-high (e.g., pulses). Therefore, the phase monitor determines that the first superconducting input signal portion IN_{PLS1} has a logic-low value and the second superconducting input signal portion IN_{PLS2} has a logic-high value for a corresponding “01” binary code. If the phase monitor determines a phase-shift of the RF output signal OUT_{RF} relative to the RF input signal IN_{RF} of approximately 180°, then the phase monitor determines that there are eight flux quanta in the SQUIDs 212, and thus the maximum, which is based on all eight of the tuning pulses TN_{PLS} being logic-high (e.g., pulses). Therefore, the phase monitor determines that each of the first and second superconducting input signal portions IN_{PLS1} and IN_{PLS2} have a logic-high value for a corresponding “11” binary code.

The above is just one example of how the superconducting readout system 200 can be arranged. As another example, the tuning pulse generator system 300 can be arranged to provide a different quantity of tuning pulses TN_{PLS}, or can provide a different allocation of tuning pulses TN_{PLS} for each superconducting bit of the superconducting input signal IN_{PLS}. For example, the first pulse splitter 304 could instead be configured to provide two tuning pulses and the second pulse splitter 310 could instead be configured to provide six tuning pulses. As another example, the tuning pulse generator system 300 could generate more or fewer than eight tuning pulses TN_{PLS} while maintaining the unique number of tuning pulses TN_{PLS} for each superconducting bit of the superconducting input signal IN_{PLS}.

As yet another example, the superconducting input signal IN_{PLS} can include fewer (e.g., one) superconducting bits, such that any phase difference between the RF output signal OUT_{RF} and the RF input signal IN_{RF} is indicative of a logic-high of the single bit superconducting input signal IN_{PLS}. As yet a further example, the superconducting input signal IN_{PLS} can include more than two superconducting bits, with each of the superconducting bits of the superconducting input signal IN_{PLS} having a unique number of representative tuning pulses TN_{PLS}, and with the sum of tuning pulses TN_{PLS} for any combination of more than one superconducting bit likewise being unique (e.g., relative to any one other superconducting bit of the superconducting input signal IN_{PLS}). For example, the superconducting input signal IN_{PLS} can have three superconducting bits, such that a first bit IN_{PLS1} can be provided to the SQUIDs 212 as a single tuning pulse TN_{PLS} (e.g., with no splitting), a second bit IN_{PLS2} can be provided to the SQUIDs 212 as two tuning pulses TN_{PLS}, and a third bit IN_{PLS3} can be provided to the SQUIDs 212 as five tuning pulses TN_{PLS}. Therefore, the superconducting readout system 200 can be fabricated to provide readout for a variety of different quantities of parallel superconducting bits based on a fabrication maximum of phase-shift and a minimum detectable phase difference of the phase monitor based on the increments of phase-shift provided by each discrete flux quantum provided to the SQUIDs 212.

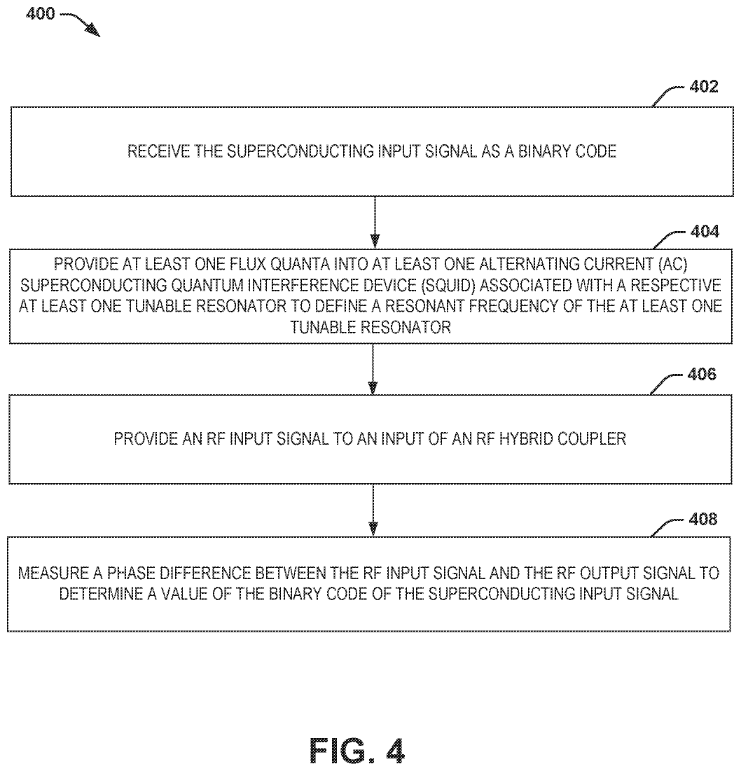

In view of the foregoing structural and functional features described above, a methodology in accordance with various aspects of the disclosure will be better appreciated with reference to FIG. 4. It is to be understood and appreciated that the method of FIG. 4 is not limited by the illustrated order, as some aspects could, in accordance with the present disclosure, occur in different orders and/or concurrently with other aspects from that shown and described herein. Moreover, not all illustrated features may be required to implement a methodology in accordance with an aspect of the present examples.

FIG. 4 illustrates an example of a method 400 for reading a superconducting input signal (e.g., the superconducting input signal IN_{PLS}). At 402, the superconducting input signal is received as a binary code (e.g., a multi-bit binary code). At 404, at least one flux quanta is provided to at least one AC SQUID (e.g., the SQUIDs 212) associated with a respective at least one tunable resonator (e.g., the tunable resonators 206 and 208) to define a resonant frequency of the at least one tunable resonator. At 406, an RF input signal (e.g., the RF input signal IN_{RF}) is provided to an input of an RF hybrid coupler (e.g., the RF hybrid coupler 102). The RF hybrid coupler can be configured to generate an RF output signal (e.g., the RF output signal OUT_{RF}) and at least one RF tuning signal (e.g., the RF tuning signal(s) TN) based on the RF input signal. The at least one RF tuning signal can be provided to and reflected back from the respective at least one tunable resonator to provide a variable phase-shift of the RF output signal relative to the RF input signal. At 408, a phase difference between the RF input signal and the RF output signal is measured to determine a value of the binary code of the superconducting input signal.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A superconducting readout system comprising:
an RF hybrid coupler configured to receive an RF input signal and to generate at least one RF tuning signal and an RF output signal based on the RF input signal;
a tunable resonator system comprising at least one tunable resonator configured to receive the respective at least one RF tuning signal, each of the at least one tunable resonator having a resonant frequency that is set by a superconducting input signal, such that the at least one RF tuning signal is reflected back to the RF hybrid coupler to provide a variable phase-shift of the RF output signal relative to the RF input signal that is based on the superconducting input signal; and
a phase monitor configured to measure a phase difference between the RF input signal and the RF output signal to determine the superconducting input signal.

2. The system of claim 1, wherein each of the at least one tunable resonator comprises:
a transmission line coupled to the RF hybrid coupler and being configured to propagate a respective one of the at least one RF tuning signal; and
an alternating current (AC) superconducting quantum interference device (SQUID) that is configured to adjust the resonant frequency of the respective one of the at least one tunable resonator based on a plurality of discrete flux quanta provided to the AC SQUID in response to the superconducting input signal.

3. The system of claim 2, wherein the at least one tunable resonator comprises a first tunable resonator and a second tunable resonator, wherein the first tunable resonator comprises a first transmission line and a first AC SQUID and the second tunable resonator comprises a second transmission line and a second AC SQUID, wherein the superconducting input signal is configured to provide the discrete flux quanta to each of the first and second AC SQUIDs.

4. The system of claim 2, wherein the tunable resonator system further comprises a tuning pulse generator system that is configured to generate a plurality of tuning pulses based on the superconducting input signal, wherein the tuning pulses are each configured to provide one of the discrete flux quanta to the AC SQUID to adjust the resonant frequency of the respective one of the at least one tunable resonator.

5. The system of claim 4, wherein the RF hybrid coupler is configured to provide the phase-shift as having a defined phase-shift angle for each flux quantum of the discrete flux quanta, such that the phase-shift of the RF output signal relative to the RF input signal is based on a quantity of the tuning pulses provided to the AC SQUID.

6. The system of claim 1, wherein the tunable resonator system further comprises a tuning pulse generator system that is configured to generate a plurality of tuning pulses based on the superconducting input signal, wherein the resonant frequency of each of the at least one tunable resonator is set based on the tuning pulses.

7. The system of claim 6, wherein the superconducting input signal is arranged as a binary code, wherein the tuning pulse generator system is configured to generate a unique quantity of the tuning pulses for each superconducting bit of the binary code.

8. The system of claim 7, wherein the tuning pulse generator system comprises at least one pulse splitter configured to convert a respective at least one superconducting bit of the binary code to a plurality of equal superconducting bits corresponding to a respective plurality of the tuning pulses.

9. The system of claim 7, wherein the unique quantity of the tuning pulses is unique for each superconducting bit and is unique with respect to a sum of tuning pulses for more than one superconducting bit of the binary code.

10. The system of claim 7, wherein the RF hybrid coupler is configured to provide the phase-shift as having a defined phase-shift angle for each of the applied tuning pulses, such that the phase-shift of the RF output signal relative to the RF input signal is indicative of the binary code based on a quantity of the tuning pulses provided to each of the at least one tunable resonator.

11. A method for reading a superconducting input signal, the method comprising:
receiving the superconducting input signal as a binary code;
providing at least one flux quanta into at least one alternating current (AC) superconducting quantum interference device (SQUID) associated with a respective at least one tunable resonator to define a resonant frequency of the at least one tunable resonator;
providing an RF input signal to an input of an RF hybrid coupler, the RF hybrid coupler being configured to generate an RF output signal and at least one RF tuning signal based on the RF input signal, the at least one RF tuning signal being provided to and reflected back from the respective at least one tunable resonator to provide a variable phase-shift of the RF output signal relative to the RF input signal; and
measuring a phase difference between the RF input signal and the RF output signal to determine a value of the binary code of the superconducting input signal.

12. The method of claim 11, wherein providing the at least one flux quanta comprises generating a plurality of tuning pulses based on the superconducting input signal, wherein the tuning pulses are each configured to provide one of the discrete flux quanta to the AC SQUID to adjust the resonant frequency of the respective one of the at least one tunable resonator.

13. The method of claim 12, wherein providing the at least one flux quanta comprises providing the phase-shift at a defined phase-shift angle for each flux quantum of the discrete flux quanta, such that the phase-shift of the RF output signal relative to the RF input signal is based on a quantity of the tuning pulses provided to the AC SQUID.

14. The method of claim 12, wherein generating a plurality of tuning pulses comprises generating a unique quantity of the tuning pulses for each superconducting bit of the binary code and a unique quantity with respect to a sum of tuning pulses for more than one superconducting bit of the binary code.

15. The method of claim 12, wherein generating a plurality of tuning pulses comprises converting a respective at least one superconducting bit of the binary code to a plurality of equal superconducting bits corresponding to a respective plurality of the tuning pulses via at least one pulse splitter.

16. A superconducting readout system comprising:
an RF hybrid coupler configured to receive an RF input signal and to generate at least one RF tuning signal and an RF output signal based on the RF input signal;
a tunable resonator system comprising:
a tuning pulse generator system that is configured to generate a plurality of tuning pulses based on a superconducting input signal; and
at least one tunable resonator comprising a transmission line and an alternating current (AC) superconducting quantum interference device (SQUID), each of the at least one tunable resonator having a resonant frequency that is set by a quantity of flux quanta in the respective AC SQUID in response to the tuning pulses, such that the at least one RF tuning signal is provided to each of the respective at least one tunable resonator and is reflected back to the RF hybrid coupler to provide a variable phase-shift of the RF output signal relative to the RF input signal that is based on the superconducting input signal; and
a phase monitor configured to measure a phase difference between the RF input signal and the RF output signal to determine the superconducting input signal.

17. The system of claim 16, wherein the superconducting input signal is arranged as a binary code, wherein the tuning pulse generator system is configured to generate a unique quantity of the tuning pulses for each superconducting bit of the binary code.

18. The system of claim 17, wherein the tuning pulse generator system comprises at least one pulse splitter configured to convert a respective at least one superconducting bit of the binary code to a plurality of equal superconducting bits corresponding to a respective plurality of the tuning pulses.

19. The system of claim 17, wherein the unique quantity of the tuning pulses is unique for each superconducting bit and is unique with respect to a sum of tuning pulses for more than one superconducting bit of the binary code.

20. The system of claim 17, wherein the RF hybrid coupler is configured to provide the phase-shift as having a defined phase-shift angle for each of the applied tuning pulses, such that the phase-shift of the RF output signal relative to the RF input signal is indicative of the binary code based on a quantity of the tuning pulses provided to each of the at least one tunable resonator.
